(19) United States
(12) Patent Application Publication
(10) Pub. No.: US 2004/0004861 A1
(43) Pub. Date: Jan. 8, 2004

(54) Differential EEPROM using pFET floating gate transistors

(75) Inventors: Shail Srinivas, Seattle, WA (US); Chad Lindhorst, Seattle, WA (US); Yanjun Ma, Issaquah, WA (US); Terry Haas, Ballwin, MO (US); Kambiz Rahimi, Redmond, WA (US); Christopher J. Diorio, Shoreline, WA (US)

Correspondence Address: David B. Ritchie, Thelen Reid & Priest LLP, P.O. Box 640640, San Jose, CA, 95164-0640, US

(73) Assignee: Impinj, Inc. A Delware Corporation

(21) Appl. No.: 10/190,337

(22) Filed: Jul. 5, 2002

(51) Int. Cl. G11C 11/34

(52) U.S. Cl. 365/185.21

(57) ABSTRACT

An electrically erasable programmable read only memory (EEPROM) cell that uses differential pFET floating-gate transistors as its core.

### FIELD OF THE INVENTION

The present invention is directed to the field of electrically eraseable programmable read-only memories (EEPROMs). More particularly it is directed to EEPROMs implemented with pFET (p channel field effect transistor) floating gate devices.

### BACKGROUND OF THE INVENTION

Many CMOS (complementary metal oxide semiconductor) integrated circuits require small amounts of on-chip nonvolatile memory (NVM). Typical applications include storing security settings, RFID (radio frequency identification) data, system configurations, serial numbers, calibration and trim settings, and others. For reasons of cost and yield, the ideal NVM should be in state-of-the-art logic CMOS with zero additional process masks. Unfortunately, applications requiring relatively small amounts of NVM (a few hundred words) have been largely neglected by the major memory manufacturers as they focus on developing customized NVM processes that yield ever-increasing memory densities (e.g. 256 Mb Flash). Consequently, CMOS designers requiring small amounts of nonvolatile storage must (1) use technologies such as on-chip fuses, (2) pay the cost and absorb the yield degradation associated with using high-density embedded NVM, (3) resort to off-chip storage, or (4) use SRAM (static random access memory) storage with its associated battery backup.

Designers needing small amounts of NVM in highly integrated CMOS applications face some unpleasant tradeoffs. The obvious approach is to use a CMOS process with embedded NVM. Unfortunately, embedded NVM processes are burdened not only with higher wafer costs, but also tend to be older-generation technology. The higher cost is due to the fact that NVM processes generally require additional masks and fabrication steps (e.g., to obtain a second polysilicon layer). The older-generation technology arises because adding NVM to a logic process takes time and testing, so NVM processes typically lag the state-of-the-art by up to a year. The result can be that, for a precious few NVM bits, an entire CMOS chip will have higher cost and reduced performance.

One alternative to embedded NVM processes is to use fuses (or anti-fuses) that are either laser or electrically programmed. Applications requiring one-time programming may find this alternative attractive, but significant technology issues such as fuse healing and/or programming cost remain problematic. Furthermore, fuses are often unavailable in state-of-the-art CMOS processes.

Another option is to use an off-chip solution such as a separate NVM chip or battery backup for on-chip SRAM. Unfortunately, this solution requires additional devices and, in the case of off-chip NVM, exposes the data to potential hacking. The benefit, of course, is that designers can implement the rest of the chip in a leading-edge technology without incurring the overhead of an NVM process. The disadvantage is higher cost, both in PCB (printed circuit board) area and parts count.

What CMOS designers need is an NVM capability in state-of-the-art logic CMOS.

### BRIEF DESCRIPTION OF THE INVENTION

An electrically erasable programmable read only memory (EEPROM) cell that uses differential pFET floating-gate transistors as its core.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a plot of drain current vs. control-gate-to-source voltage for a floating gate MOSFET.

FIG. 2 is a MOS energy-band diagram and elevational cross-section for a device in accordance with an embodiment of the present invention.

FIG. 3 is an electrical schematic diagram of one embodiment of the present invention. A pFET M2 is used to set the differential-pair bias current with the signal “bias” and floating-gate pFETs M0 and M1 act as the storage devices. Shorted pFETs TunJun0 and TunJun1 are used to remove charge from the floating gates and/or act as control gates. TunJun0 and TunJun1 could alternatively be implemented using shorted nFETs, as is well known to those practiced in the art.

FIG. 4 is a plot of injection efficiency versus gate-to-drain voltage, where injection efficiency is defined as gate current divided by source current.

FIG. 5 is an electrical schematic diagram of an alternative embodiment of the invention comprising a differential cell without tunneling junctions. The floating gates are erased using UV light or other techniques well known to those in the art, and the cell may be one-time programmed using injection.

FIG. 6 is an electrical schematic diagram of a differential cell with select transistors to decide which side of the cell undergoes injection in accordance with an embodiment of the present invention.

FIG. 7 is an electrical schematic diagram of a differential cell with the tail connected to a pFET current source and the select transistors (M0, M1) implemented with nFETs in accordance with an embodiment of the present invention.

FIG. 8 is an electrical schematic diagram of a differential cell in which the current is controlled at the drains of the floating-gate injection transistors in accordance with an embodiment of the present invention. Since there are two separate current controls, IHEI can be controlled separately in M0 and M1.

FIG. 9 is an electrical schematic diagram of a version of the circuit of FIG. 8 in accordance with an embodiment of the present invention. In this version, applying a positive bias voltage to either bias0 or bias1 and applying 0V to the other signal will write the cell.

FIG. 10 is an electrical schematic diagram of an embodiment of the present invention including a pFET read transistor associated with each floating gate.

FIG. 11 is an electrical schematic diagram of an embodiment of the present invention similar to that of FIG. 10, but including row select transistors (M0, M1) to isolate cells from the differential sense amplifier.

FIG. 12 is an electrical schematic diagram of an alternate portion of the circuit contained in box 12 of FIG. 11 in accordance with one embodiment of the present invention.

FIG. 13 is an electrical schematic diagram of an embodiment of the present invention implementing bidirectional tunneling.

FIG. 14 is an electrical schematic diagram of an alternate embodiment of the present invention based on that of FIG. 13. In this version the cell is written by electron injection, and a pFET read transistor is associated with each floating gate.

FIG. 15 is an electrical schematic diagram of an embodiment of the present invention where one half of the differential cell is shared by all cells in a row of the memory. This embodiment is particularly useful for memory banks of differential cell-type memory.

FIG. 16 is an electrical schematic diagram of an embodiment of the present invention that modifies the version of FIG. 14 by adding a pair of floating-gate transistors (M2, M3) to monitor the end of the tunneling process.

FIG. 17 is an electrical schematic diagram of an embodiment of the present invention that illustrates how to use feedback to judiciously apply small amounts of IHEI to a cell during tunneling, to prevent over-tunneling the cell.

FIG. 18 is an electrical schematic diagram of an embodiment of the present invention presenting a simplification of the cell of FIG. 17. The Read_not signal is used to configure the cell for read mode. FIGS. 19 and 20 are electrical schematic diagrams of an embodiment of the present invention that illustrate that the cell current can be controlled at the drain side of the injection transistors. The embodiment of FIG. 20 has an explicit nFET current sink M0 that controls the write and read currents.

FIG. 21 is an electrical schematic diagram of a single differential memory cell in accordance with one embodiment of the present invention.

FIG. 22 is an electrical schematic diagram of a circuit for sensing the completion of the tunneling process in accordance with one embodiment of the present invention.

FIG. 23 is an electrical schematic diagram of a circuit for sensing the completion of injection in accordance with an embodiment of the present invention.

### DETAILED DESCRIPTION

Embodiments of the present invention are described herein in the context of a differential electrically erasable programmable read-only memory using pFET floating gate transistors. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

The present invention applies generally to nonvolatile memories, and has particular application in low-density embedded nonvolatile memories as might be found in embedded CMOS applications. Such embedded CMOS applications include storing: (1) chip serial numbers (i.e. chip tags), (2) configuration information in ASICs (application specific integrated circuits), (3) product data in radio frequency identification (RFID) integrated circuits, (4) code or data in embedded microcontrollers, (5) analog trim information, and (6) a host of other applications as will now be apparent to those skilled in the art. Compared with conventional nFET-based nonvolatile memories, using pFETs has at least the advantages of decreased charge pump power, increased program/erase cycling endurance (due to reduced oxide wearout), and availability in logic CMOS processes (due to reduced memory leakage and the fact that the cell uses only nFETs and pFETs).

Any reprogrammable NVM technology must meet two key requirements: (1) endurance and (2) retention. Endurance refers to the number of erase/write cycles (real NVM has an unlimited number of read cycles). Retention refers to the memory storage time. The evolution of flash and EEPROM technologies over the past two decades has resulted in a set of commercially accepted design standards for NVM. Any design in a standard CMOS process should meet these same standards. The two standards are 10-year retention and 10,000 (minimum) erase/write cycles.

NVM devices store information by changing the physical attributes of a transistor or other circuit element. In the case of floating-gate memories (e.g. Flash or EEPROM), the physical attribute is the quantity of electrons stored on the electrically isolated (floating) gate of a silicon MOSFET (metal oxide semiconductor field effect transistor). All NVM devices wear out, meaning that after a certain number of write/erase cycles the memory will no longer meet its 10-year retention requirement. In the case of floating-gate memories, wearout occurs because moving electrons through the oxide insulator surrounding an electrically isolated gate invariably damages this insulating oxide. Modem NVM typically provides 10,000 erase/write cycle endurance and often 100,000 to 1,000,000 erase/write cycle endurance.

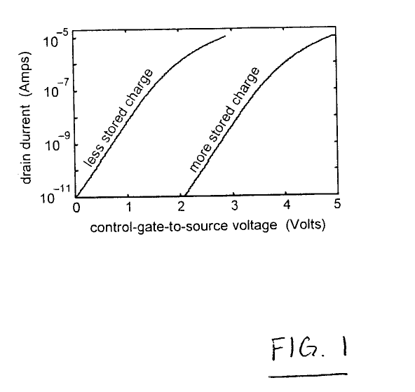

Floating-gate memory technologies store information as electrons on the floating gate of a silicon MOSFET. Adding or removing electrons from the floating gate changes the MOSFET's threshold voltage bidirectionally. FIG. 1 is a plot of drain current vs. control-gate-to-source voltage for a floating gate MOSFET. To read the memory, one measures the floating-gate MOSFET's channel current. If the left curve in FIG. 1 is observed, then the stored memory is a logic “1”. If the right curve in FIG. 1 is observed, then the stored memory is a logic “0”.

NVM designers can use either n-channel or p-channel floating-gate MOSFETs as memory transistors. Since the early 1980s they have used n-channel MOSFETs, because of small cell size and the existence of direct methods for injecting an nFET's channel electrons onto a floating gate. This choice enables high-density Flash and EEPROM in highly modified CMOS processes. In logic CMOS, however, the situation is reversed-pFETs are far superior to nFETs, for two reasons:

1) pFET NVM has better retention that nFET NVM

2) pFET NVM allows more erase/write cycles than nFET NVM

Of course, there are disadvantages to using pFET NVM. pFET NVM has a larger cell size than the NFET NVM found in customized processes, and tends to have longer write times. For small memories (i.e., those of less than or equal to about 64 kbits), these disadvantages are significantly outweighed by the retention and endurance benefits and by the zero process-mask increase.

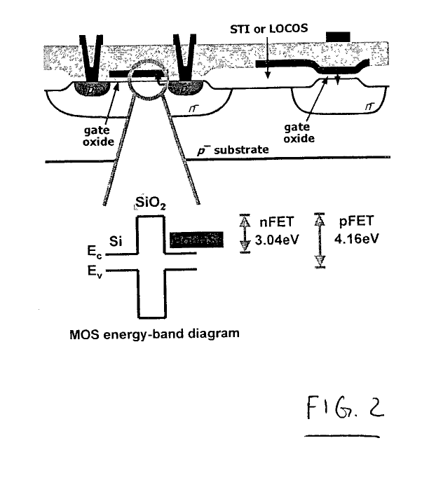

FIG. 2 is a MOS energy-band diagram and elevational cross-section for a device in accordance with an embodiment of the present invention. FIG. 2 illustrates why pFET NVM has better retention than nFET NVM. Device physics shows that the energy barrier for electron leakage from apFET is 4.16 eV, whereas that for an nFET is only 3.04 eV. This difference means the pFET cell, with its higher energy barrier, will exhibit significantly less electron tunneling through the gate oxide than an nFET cell at the same oxide thickness. In a custom CMOS process this difference is of no real consequence, because the process engineers merely thicken the gate oxide until the cell has 10-year retention. All current commercial nFET-based NVM cells use 80 Å or thicker oxides. Unfortunately, there are no 80 Å oxides in modem logic CMOS (0.35 μm and smaller process linewidths). Consequently, nFET NVM in logic CMOS, constructed with 70 Å or thinner gate oxides, simply cannot meet the 10-year retention requirement over process corners and temperature. The solution is to use pFET NVM. A 3.3V pFET with 70 Å oxide, as is available in modem dual-gate-oxide CMOS processes, has the same data retention as an 82 Å nFET in a customized process. In short, retention is key to NVM, and pFETs have 10-year retention in logic CMOS whereas nFETs don't.

U.S. Pat. No. 5,990,512, Hole Impact Ionization Mechanism of Hot Electron Injection and Four Terminal pFET Semiconductor Structure for Long-Term Learning, by Diorio, et al, describes a method for transferring charge to and from the gate of a floating gate pFET. The present invention uses floating gate pFETs as the memory storage transistors, with the Impact-ionized Hot Electron Injection (IHEI) and tunneling methods described in the '512 patent used to write the memory cells. Because IHEI and tunneling do not require special device processing, floating-gate devices can be built using the same IC processing as that used to make standard digital logic transistors.

There are three main challenges when using floating-gate pFETs as nonvolatile memory transistors in standard CMOS processes:

1) In conventional nFET based EEPROM or flash memories, the user applies a read voltage to a capacitor coupled to the floating gate to enable the read operation. InpFET memories fabricated in standard processes there is typically no capacitor to couple to the floating gate, either complicating the read or requiring that the designer add another transistor (a MOSCAP) to the floating gate to use as a capacitor input.

2) One characteristic of the IHEI programming method used in pFETs is that the MOSFET channel must be conducting current to cause electron injection. Thus to use a pFET storage transistor one must keep the transistor conducting in both the “1” and “0” states. The alternative, if the pFET becomes completely turned off, is to use a mechanism such as band-to-band tunneling at the transistor's drain to generate injection electrons. This latter mechanism both causes device damage and is slow, so it should be avoided by ensuring that the pFET channel is always on.

3) The electron injection rate is small at both low and high channel currents [C. Diorio, et al, IEEE Trans. Electron Device, vol. 44, pp. 2281-2289 (1997)], limiting the range of channel currents to which the transistor can be programmed. This small programming range translates into a small floating-gate voltage range between the written and erased states (called the “storage window”). A small storage window means that pFET cells are more sensitive to charge loss than nFET cells, because small amounts of charge loss can change the memory state more easily inpFETs than in nFETs.

These three problems are solved with the present invention by using a differential cell. Furthermore, as described below, the differential cell design has many added benefits such as low power consumption, high read speed, and reduced sensitivity to process variations, temperature and power supply fluctuations. Consequently, the combined approach of using (1) a pFET-based memory and (2) a differential cell enables NVM in logic CMOS.

By using a differential cell instead of a standard single-ended cell, the present invention exhibits increased read speed, decreased read current and power consumption, decreased sensitivity to variations in tunneling and injection efficiency, relaxed requirements for precision on-chip current and voltage references, and reduced temperature and supply-voltage sensitivity.

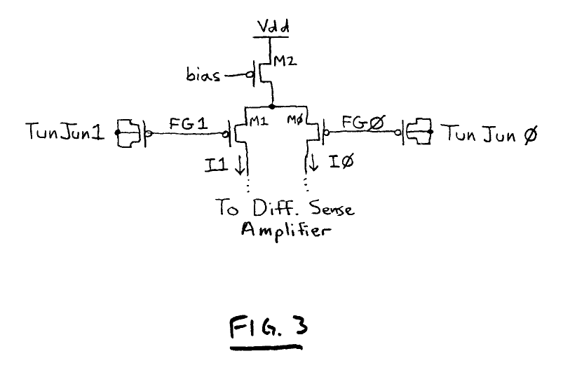

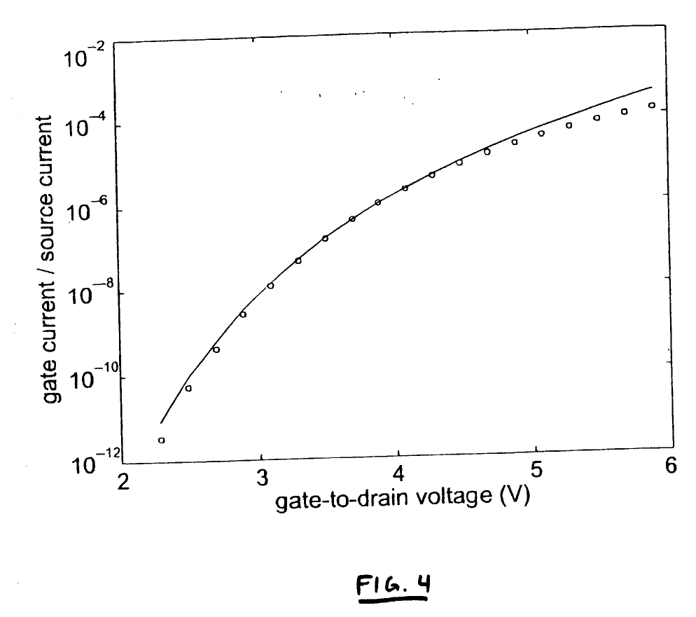

FIG. 3 is an electrical schematic diagram of one embodiment of the present invention. A pFET M2 is used to set the differential-pair bias current with the signal “bias” and floating-gate pFETs M0 and M1 act as the storage devices. Shorted pFETs TunJun0 and TunJun1 are used to remove charge from the floating gates and/or act as control gates. TunJun0 and TunJun1 could alternatively be implemented using shorted nFETs, as is well known to those practiced in the art. The logic state of the differential cell is determined by the difference in charge stored on the two floating gates rather than on the on-off state of a single cell as is common in nFET-based NVM. Regardless of whether the cell stores a logic 0 or a logic 1, both transistors have an inverted channel.

The erase cycle of the basic cell works as follows. The differential cell is erased by using Fowler-Nordheim tunneling to remove electrons from both floating gates. This is done in accordance with one embodiment of the invention by bringing both tunneling junctions (TunJun1 and TunJun0) to about 10V. To stop the erase process before the pFET floating-gate transistors tunnel to a completely off state, the drain currents (I1 and I0) are monitored in a conventional manner during the erase process. A tunneling done (TunDone) signal is generated in a conventional manner once the drain currents of a particular cell reach a predetermined minimum value (e.g., about 10 nA). This signal can be used to stop the tunnel process on that floating gate or on a block of floating gates. This feedback process ensures that no floating-gate transistor is completely turned off when erased.

The program cycle of the basic cell works as follows. To program a logic 1 to a cell, a bias current is applied to the cell using transistor M2 while a large drain-to-source voltage is applied across transistor M1 (by applying a low or negative voltage to M1's drain). Typical values are Vdd=1.8V,V_M1_{drain}=−3.3V. Transistors M2 and M1 conduct, and electrons inject onto floating gate FG1 using the IHEI process discussed in U.S. Pat. No. 5,990,512. The same procedure is followed to write a logic 0, except transistor M0 is injected instead of M1.

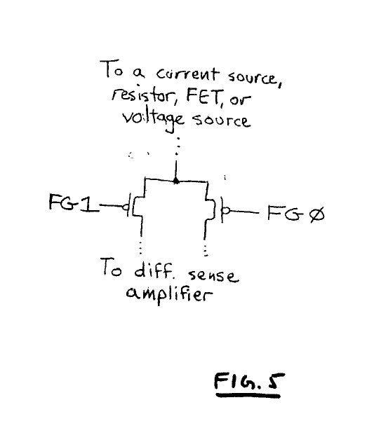

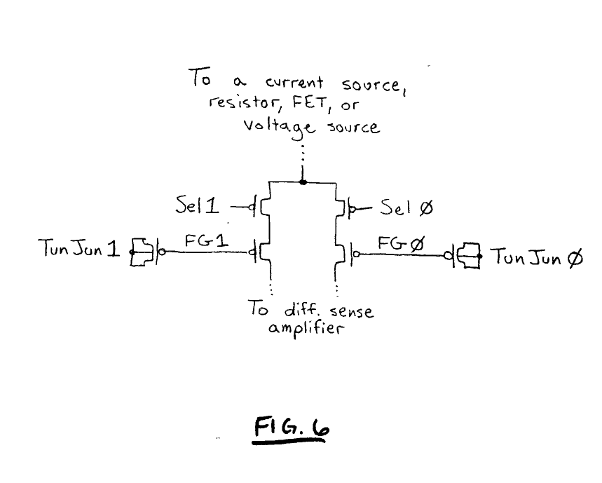

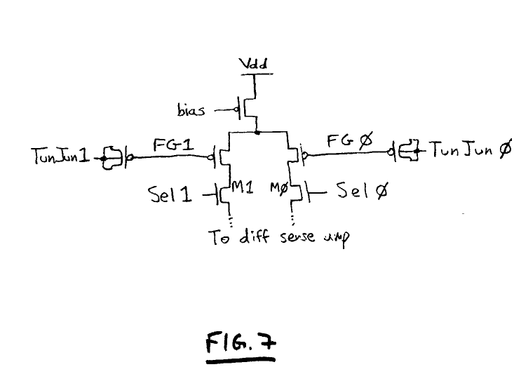

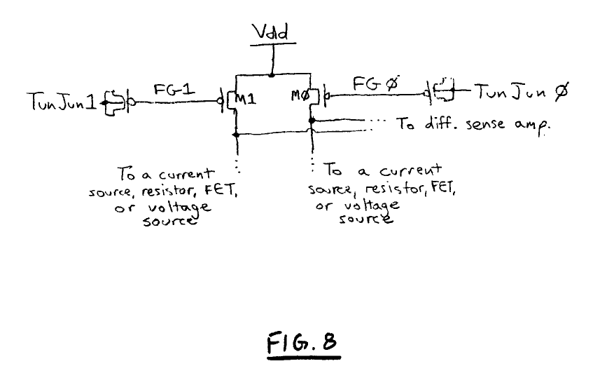

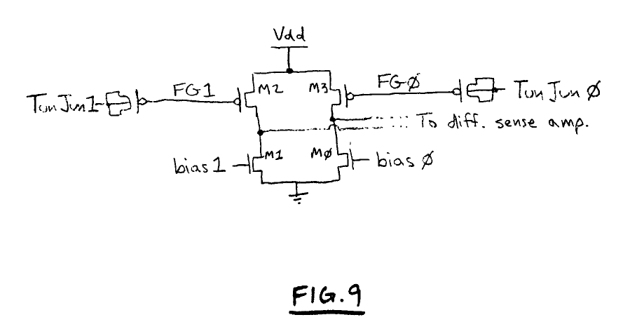

The injection process is self-limiting, meaning that as electrons inject onto a floating gate the transistor itself stops the injection process. Unlike an nFET, a pFET will self-limit its IHEI current because injection causes its floating gate voltage to drop. As the gate voltage drops, so does the injection transistor's drain-to-gate voltage. Because IHEI decreases exponentially with decreasing drain-to-gate voltage (as illustrated in FIG. 4 which is a plot of gate current/source current vs. gate-to-drain voltage), the transistor itself stops the IHEI process.

Alternatively, those of ordinary skill in the art will now realize that one can also create a signaling circuit that could be used to terminate the injection process, e.g., by halting the current through transistor M2 when the floating gate of the injection transistor reaches a predetermined voltage.

The read cycle of the basic cell works as follows. To read the contents of a differential cell, a bias current is first applied to the cell using transistor M2. A read operates on the principle of distinguishing the more conductive path between the two halves of the differential cell. If FG0 has a lower voltage than FG1, then M0 will be more conductive and the bias current will pass as I0. If FG1 has a lower voltage than FG0, the complementary case holds. A conventional differential sense amplifier then decides whether the cell holds a logic 1 or logic 0 by comparing I0 and I1. Because the cell is differential, we can use arbitrarily small bias currents in transistor M2 while reading the cell. Consequently, the cell can use arbitrarily low power during read operations.

FIG. 5 is an electrical schematic diagram of an alternative embodiment of the invention comprising a differential cell without tunneling junctions. The floating gates are erased using electromagnetic radiation such as UV light shown upon the floating gates through an appropriate window in the package containing the device or other techniques well known to those in the art, and the cell may be one-time programmed using injection. In this manner the layout area associated with the tunneling junctions is saved. The option to remove the tunneling junctions applies to all embodiments of this invention as does the option to put the tunneling junctions in either the same or in separate n-wells of the substrate. If the tunneling junctions are formed in separate n-wells, single nodes (i.e. single sides) of the cell can be selected for erasure. If the tunneling junctions are formed in the same n-well, die area is conserved and both sides of the differential cell are erased at the same time. The precise configuration to use in a particular implementation will be up to the designer.

In the embodiments of the present invention that use tunneling junctions, these can be implemented in a number of ways. Generally a separate n-well is disposed apart from the n-well in which the IHEI transistor is located. The floating gate is disposed over both n-wells. The tunneling junction may be an n+ region disposed in the n-well, a shorted nFET (with drain and source connected together), a shorted pFET (with drain, source and well contact connected together), or other arrangements as will now be apparent to those of ordinary skill in the art. See FIG. 2 for the general layout of a cell in accordance with one embodiment of the present invention.

FIG. 6 is an electrical schematic diagram of a differential cell with select transistors to decide which side of the cell undergoes injection in accordance with an embodiment of the present invention. The advantage of the cell of FIG. 6 over the cell in FIG. 3 is that the drains of both injection transistors can be brought low during injection, and one side may be selected for writing by enabling its corresponding select transistor. The tail of this differential pair can be connected to either a current source as in FIG. 3, or to a voltage source through a resistor.

FIG. 7 is an electrical schematic diagram of a differential cell with the tail connected to a pFET current source and the select transistors (M0, M1) implemented with nFETs in accordance with an embodiment of the present invention. The cell is programmed by pulling Vdd high (to about 5V), turning one of the select transistors (M0, M1) on by tying its gate voltage to Vdd, and turning off the other select transistor by tying its gate to ground. The floating gate transistor on the “on” side will undergo IHEI, causing its gate voltage to drop. The floating-gate transistor on the “off” side won't have any channel current, reducing its injection to negligible levels and causing the gate voltage to remain essentially unchanged.

In an alternative embodiment, the select transistors in FIG. 7 can be implemented with pFETs. The select transistors in FIG. 7 can also be used to separate multiple cells from a single sense amplifier.

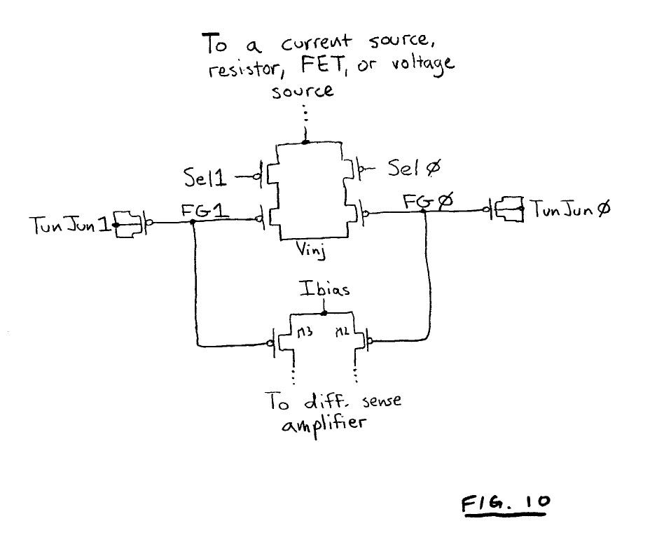

FIG. 8 is an electrical schematic diagram of a differential cell in which the current is controlled at the drains of the floating-gate injection transistors in accordance with an embodiment of the present invention. Since there are two separate current controls, IHEI can be controlled separately in M0 and M1. FIG. 9 is an electrical schematic diagram of a version of the circuit of FIG. 8 in accordance with an embodiment of the present invention. In this version, applying a bias voltage to either bias0 or bias1 and applying 0V to the other signal will write the cell. If bias0 is set to a bias voltage and bias1 is set to 0V, current will flow through M0 and M3, causing IHEI in M3 and lowering the voltage on FG0. In this case, no current will flow through M1 and M2, so the injection rate at M2 will be much smaller than that at M3. The complimentary case holds when bias1 is set to a bias voltage and bias0 is set to 0V. Both bias0 and bias1 can be set to Vdd during read, preventing current from bypassing the sense amplifier. In an alternative embodiment of the circuit of FIGS. 8 and 9, transistors M0 and M1 can be written independently so that the memory can store two bits of information rather than one.

The read operation for the cells of FIGS. 6, 7, 8 and 9 is similar to that described for FIG. 3.

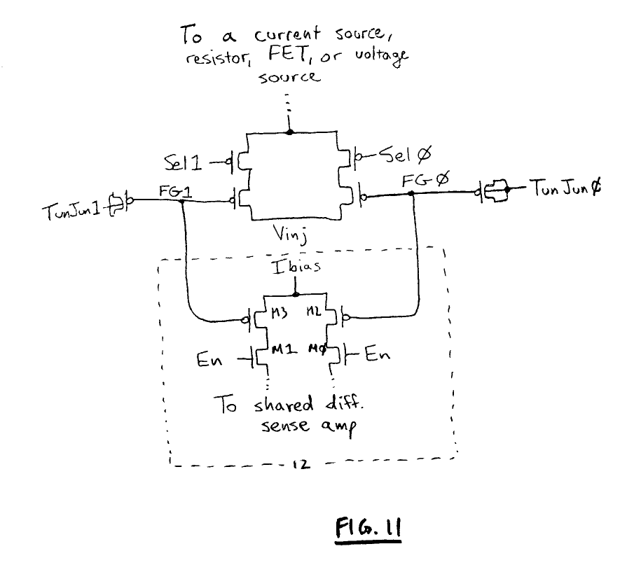

The program and read functions can be separated by adding a pFET read transistor (M2, M3) to each floating gate (see FIG. 10). FIG. 10 is an electrical schematic diagram of an embodiment of the present invention including a pFET read transistor associated with each floating gate. This modification allows the drain voltage (Vinj) of the injection transistor to be brought below ground, accelerating the IHEI process during writes. It also adds flexibility in the design of the differential sense amplifier.

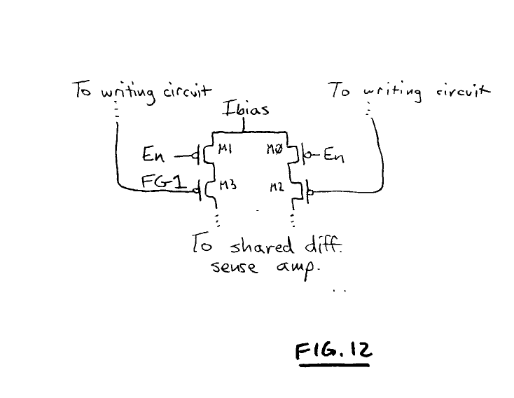

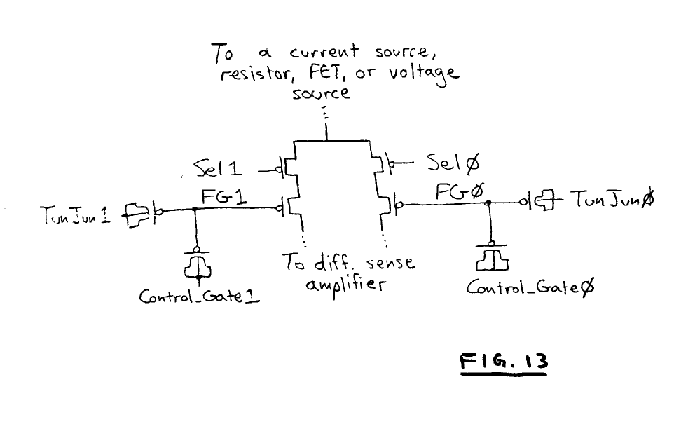

FIG. 11 is an electrical schematic diagram of an embodiment of the present invention similar to that of FIG. 10, but including row select transistors (M0, M1) to isolate cells from the differential sense amplifier. This change allows multiple cells to share a single sense amp (not shown in the figure). The select transistors (M0, M1) can be either nFETs (as shown in the figure) or pFETs.

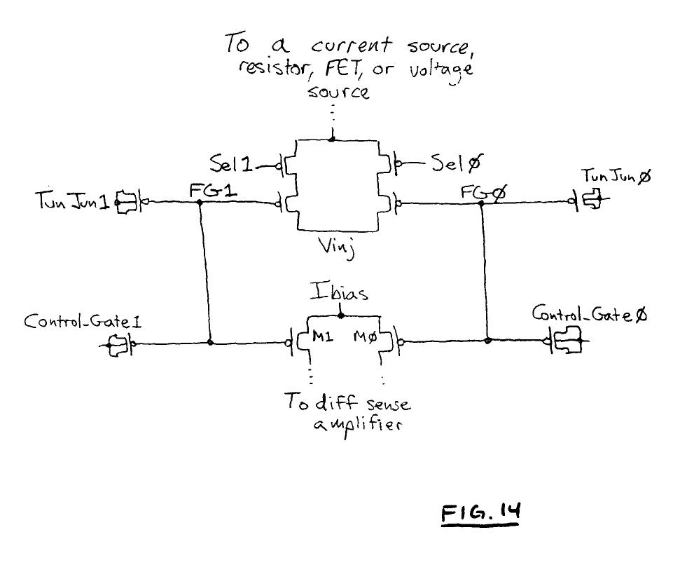

FIG. 12 is an electrical schematic diagram of an alternate portion of the circuit contained in box 12 of FIG. 11 in accordance with one embodiment of the present invention. In this alternate embodiment the select transistors are pFETs and are in a different arrangement with the read transistors M2, M3. The effect is the same.

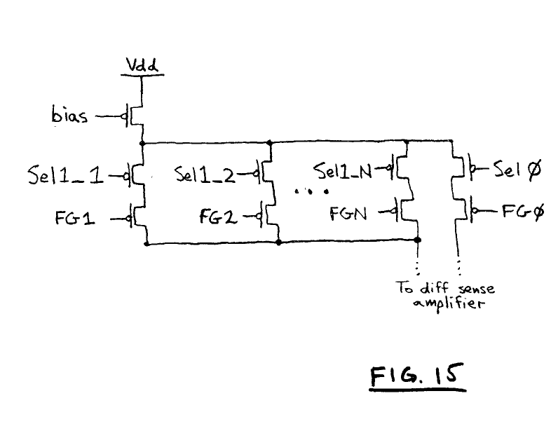

FIG. 13 is an electrical schematic diagram of an embodiment of the present invention implementing bidirectional tunneling. In this embodiment bidirectional Fowler-Nordheim (FN) tunneling is used for program/erase rather than FN tunneling and IHEI. To enable bidirectional tunneling in a single-well CMOS process, cell control gates are added (in this case MOSCAPs) that capacitively couple to the floating gate, allowing the floating-gate voltage to be moved. To program the cell, one of the MOSCAP control gates is brought to a high voltage (Vcg is about 10V) and the tunneling junction is brought to ground. By using a large control-gate MOS capacitor relative to the tunneling junction, the floating-gate voltage is brought close to Vcg by capacitive coupling, and electrons tunnel from the tunneling junction onto the floating gate. To erase the cell, the tunneling junction is brought high (to about 10V) and the control gate is pulled to ground. Electrons tunnel off the floating gate to the tunneling junction. The control gates in FIG. 13 can also be useful in cells such as the one illustrated in FIG. 3 because they can bias the floating gate to maximize writing efficiency. The MOSCAPs shown in FIG. 13 are disposed in separate n-wells. These two MOSCAPs could also share a single n-well to save area. To save even more area, at the expense of reduced MOSCAP capacitance, they can be placed in the same n-well as the other pFETs in the cell.

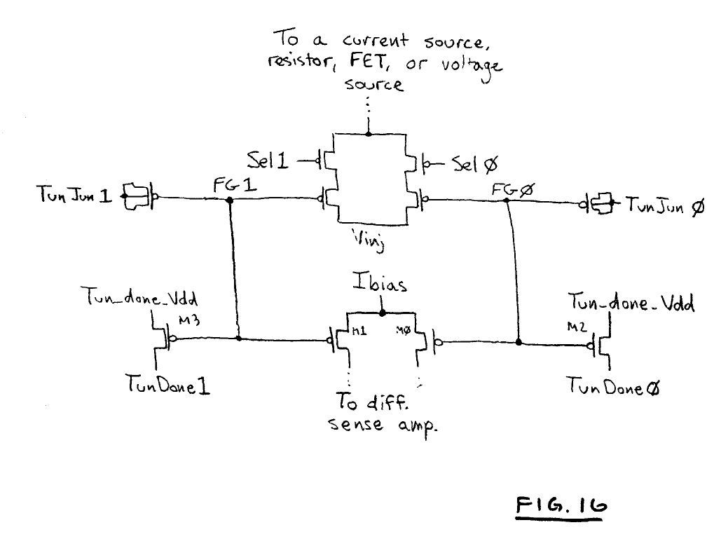

FIG. 14 is an electrical schematic diagram of an alternate embodiment of the present invention based on that of FIG. 13. In this version a sense amplifier is added to the cell of FIG. 13, and the cell is written by injection rather than by bidirectional tunneling. If a pFET is initially off, the floating-gate voltage can be pulled down through capacitive coupling, facilitating starting the injection process. Alternatively, the control gate can be used to end the tunneling process by pulling the floating gate high when tunneling is done, decreasing the oxide voltage (i.e. decreasing the difference between the tunneling voltage and the floating-gate voltage) and with it the tunneling current. This latter example requires sensing and feedback circuits as can now be easily designed by those of ordinary skill in the art. The control-gate transistors used here have the same options associated with their n-well connections as the control-gate transistors in FIG. 13.

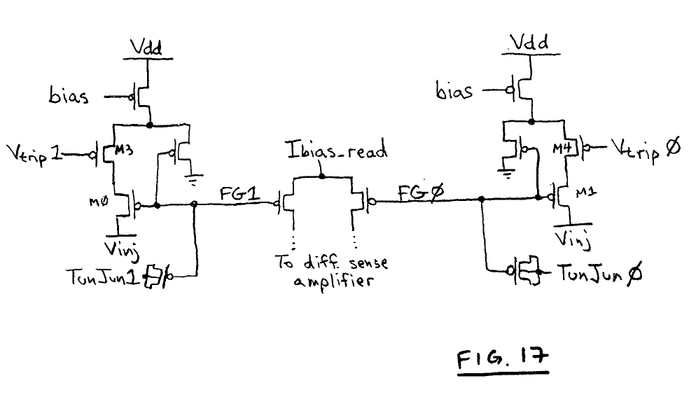

FIG. 15 is an electrical schematic diagram of an embodiment of the present invention where one half of the differential cell is shared by all cells in a row of the memory. In the embodiment illustrated in FIG. 15, plural left-side differential pairs share a common right-side. In this embodiment the shared cell is written to half way between a logic 0 and a logic 1 state, and each of the unshared cells to either a 0 state or a 1 state depending on the stored value. Alternatively, there could be two shared cells, one of which is written to a logic 0 state and the other to a logic 1 state, and the 0 and the 1 are averaged during a read operation to generate a value half way between 0 and 1. In this fashion the differential cell switches to one side or the other during a read operation, depending on whether the stored value is a 0 or a 1. During readout, Sell_x is set to Vdd for all x except one. (This is used as a bit select.). Alternatively, there could be N sense amplifiers for the N cells, to allow reading of an entire row of cells at one time. In this latter case there could be zero bias transistors (i.e., the sources of all the select transistors are tied to Vdd), one bias transistor (as shown), or N bias transistors (one for each half cell). During readout, all the Selx_N lines are brought to a low voltage at the same time, enabling all of the cells and allowing multibit reads.

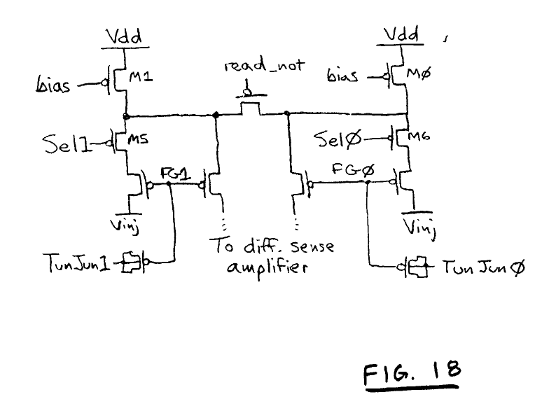

FIG. 16 is an electrical schematic diagram of an embodiment of the present invention that modifies the version of FIG. 14 by adding a pair of floating-gate transistors (M2, M3) to monitor the end of the tunneling process. Those skilled in the art can now use the TunDone0 and TunDone1 signals generated by the circuit to enable/disable the tunneling process. This design is particularly useful for ensuring that tunneling doesn't completely turn off any of the pFET floating-gate transistors in a memory.

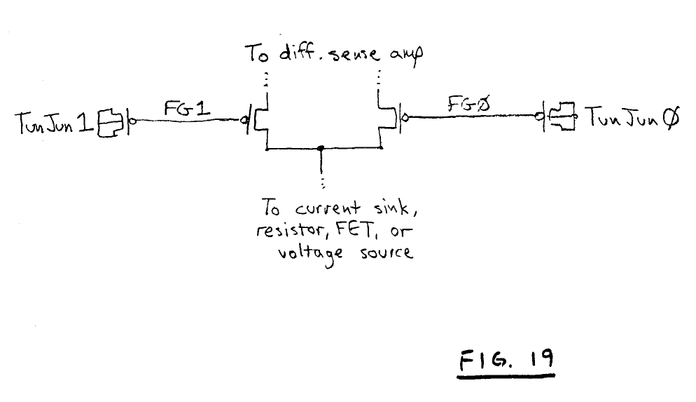

FIG. 17 is an electrical schematic diagram of an embodiment of the present invention that illustrates how to use feedback to judiciously apply small amounts of IHEI to a cell during tunneling, to prevent over-tunneling the cell. As the floating gate (FG0 or FG1) increases in voltage, increasing amounts of current flow through injection transistors (M0, M1). The net result is that, when the floating gate has tunneled to its high voltage, the number of electrons added to the floating gate by IHEI is equal and opposite to the number of electrons removed by tunneling. In this state, the floating-gate voltage is stable. Careful design of the regulation circuit allows the final floating-gate voltage to be determined by the designer. (It is largely dependant on the voltage of Vtrip (Vtrip0, Vtrip1) shown in the figure.) This method ensures that the memory cells never turn completely off, and allows for erasure that is largely independent of tunneling rate mismatch, IHEI mismatch, device mismatch, and other operating conditions. Furthermore, the regulation circuit can generate a “TunDone” signal similar to the one described above with respect to FIG. 16.

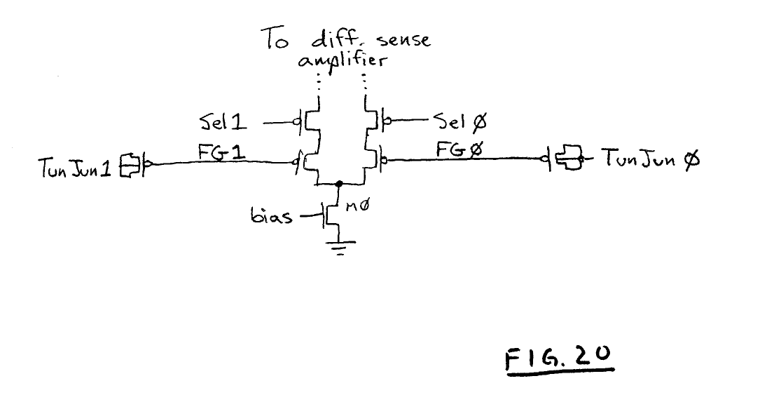

FIG. 18 is an electrical schematic diagram of an embodiment of the present invention presenting a simplification of the cell of FIG. 17. The Read_not signal is used to configure the cell for read versus write/erase mode. During write/erase, the Read_not transistor is turned off, separating the cell into two half-cells and simplifying writing/erasing. During read, the Read_not transistor is turned on and the two current sources M0 and M1 combine to form a single current source that supplies the equivalent of Ibias_read in FIG. 17. M5 and M6 are used as select transistors during injection, and as current controllers during tunneling. (They take on the same role as M3 and M4 in FIG. 17.)

FIGS. 19 and 20 are electrical schematic diagrams of an embodiment of the present invention that illustrate that the cell current can be controlled at the drain side of the injection transistors. The embodiment of FIG. 20 has an explicit nFET current sink M0 that controls the write and read currents. Sel0 and Sel1 have similar functions to the same signals in the cells of FIG. 6. The differential sense amplifier for these cells must accept current in reverse polarity compared to the amplifiers for the cells presented above. Note that this form of current control can also be applied when the read and write functions are separated, as in FIG. 10.

In the NVM application, a pFET floating gate transistor has several advantages over an nFET:

1. A p-channel floating-gate MOSFET can inject electrons onto its floating gate at smaller channel currents that is typical for n-channel floating-gate MOSFETs. Consequently, charge pumps (circuits normally required on-chip in order to provide voltages in excess of Vdd used for erase and write operations) for pFET-based memories typically consume less power than those designed for NFET cells.

2. IHEI in pFETs generates predominantly channel hot electrons, whereas the equivalent mechanism in nFETs (channel hot-electron injection or CHEI) generates channel hot holes. Because hot electrons damage gate oxide much less than hot holes, pFETs have reduced oxide wearout and better program/erase cycle endurance than do corresponding nFET memory devices.

3. The barrier height for electrons tunneling off a floating-gate pFET with a p+ doped gate is about 4.2 eV (see FIG. 2) as compared with about 3.04 eV for an nFET with an n+ doped gate. Consequently, leakage currents are smaller in pFETs than in nFETs, so the data retention characteristics of pFET floating-gate memories are better than those of nFET floating-gate memories with the same oxide thickness. As a result, pFET memories can use thinner gate oxides, such as the 70 Å oxides found in standard dual-gate-oxide CMOS processes (with 3.3V I/O devices). By comparison, memories based on nFET floating gate transistors need additional process steps to make thicker gate oxides (typically 80 Å minimum thickness).

In the NVM application, a differential cell has several advantages over a single-ended cell:

1. The logic state of a differential cell is determined by the difference in charge on the two floating gates. When there are more electrons on the “1” floating gate than electrons on the “0” floating gate, the read current will pass primarily through the transistor with the “1” gate, and vice versa. Consequently, it is possible to distinguish the logic 1 and logic 0 states while both floating gates are negatively charged with respect to the n-well voltage. This property implies that neither side has such a high gate voltage that it cannot be subsequently turned on and injected.

2. Charge leakage mechanisms tend to cause charge on both the “1” and “0” floating gates to leak in the same direction (i.e. both cells leak charge either onto their gates or off of their gates in a common direction). A differential cell has common-mode rejection, meaning that it is sensitive to the voltage difference between the floating gates rather than to their absolute voltages. Consequently, common-mode charge leakage does not affect the stored logic state. Therefore the retention of the differential cell is superior to that of single-ended cells.

3. The read operation uses the principle of distinguishing the more conductive path between the two halves of the differential cell. Arbitrarily small tail currents can be used when reading a cell, as long as the sense amplifier has adequate sensitivity to determine which path the current takes through the cell. Consequently, the cells described herein allow for low power memory circuits.

4. Because the two halves of a differential cell are usually in close proximity on a chip, they are usually well matched in transistor characteristics. For example, the gate oxide thicknesses of two adjacent floating gate transistors match more closely than those of two transistors spaced far apart. As a result, a differential cell design is less sensitive to transistor variations that could affect the read accuracy of single-ended cells.

5. A differential cell is self-referencing, meaning that one side of the cell is the reference for the other side. Consequently, differential cells eliminate the need for precision on- or off-chip current or voltage reference circuits typical in single-ended memory cells. This self-referencing property holds whether each cell is differential, as in FIG. 3, or whether multiple cells share a single half-cell, as in FIG. 15.

6. Because the differential cell is self-referencing, it has excellent common-mode rejection. Common-mode rejection gives the differential cell better immunity to power-supply and temperature fluctuations than single-ended cells.

7. A differential NVM cell has a differential output similar to that of SRAM cells well known in CMOS design. Consequently, a differential NVM cell can use the ultra-fast sense amplifiers and bit-line precharging techniques common in SRAM design (and well known to those of ordinary skill in the art and which are not further described herein to avoid overcomplicating this disclosure). The result is that differential NVM cells allow faster reads with lower power consumption than single-ended cells.

In summary, differential cells based on pFET floating gate transistors have many advantages over single-ended cells, over NFET cells, and over differential nFET cells. They enable low power, high speed, and high reliability NVMs in logic CMOS.

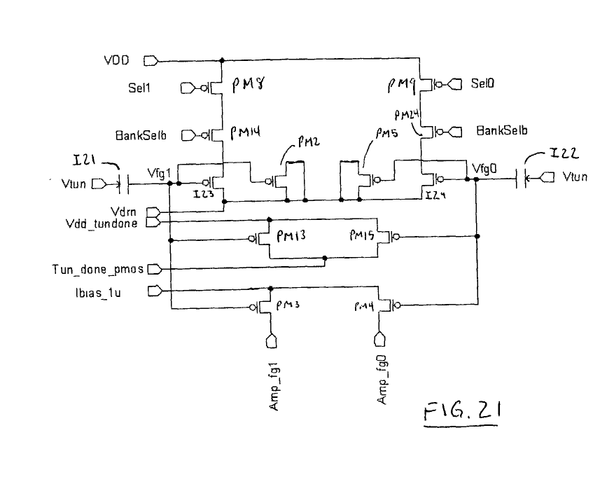

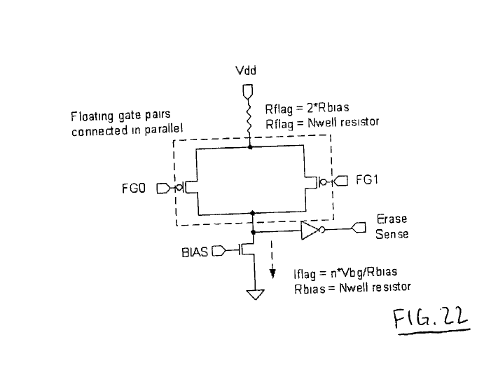

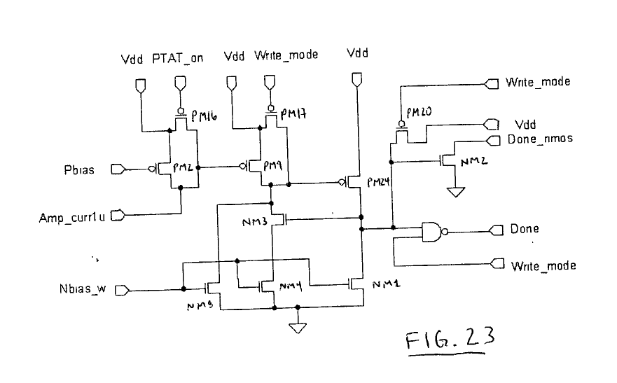

FIG. 21 is an electrical schematic diagram of a single differential memory cell in accordance with one embodiment of the present invention. FIG. 22 is an electrical schematic diagram of a circuit for sensing the completion of the tunneling process in accordance with one embodiment of the present invention. It is useable with the circuit of FIG. 21. FIG. 23 is an electrical schematic diagram of a circuit for sensing the completion of injection in accordance with an embodiment of the present invention. It is useable with the circuit of FIG. 21. The read mechanism and the write control (injection) mechanism in this embodiment of FIGS. 21, 22 and 23 have been separated. This configuration allows for a wide margin between the minimum differential voltage required to discriminate the stored level (which depends on the gain/gₘ of the readout differential pair) and the actual stored differential voltage. That margin is crucial for robust storage.

Sel0 and Sel1 are active low select signals, which determine whether a logic 0 or a logic 1 is written in the memory, respectively. Both floating gates, Vfg0 and Vfg1 are connected to five devices each:

1. Tunneling device (I21/I22): This device performs the erase operation on the cell by removing electrons from the floating gates.

2. Injection device (I23/I24): Injection devices program a memory cell by adding electrons to the selected floating gate.

3. Injection capacitors (PM2/PM5): These devices facilitate injection by increasing the capacitive coupling of the floating gates to the node Vdrn.

4. Pulse tunneling flags (PM13/PM15): Connected to Vdd through a resistor, these devices form a wired-AND gate terminated at the top level in a selectable current source to ground. They signal completion of the erase process.

5. Differential Pair (PM3/PM4): The readout stage has a common bias current source and is connected to the sense amp via an 8:1 differential multiplexer.

Those of ordinary skill in the art will now realize that variations on this design are possible by deleting or adding devices from this group of floating gate devices.

The erase function operates as follows. The tunneling junctions are pulsed high to the required voltage ˜10V. A HIGH level on the tunneling flag between pulses indicates completion of tunneling. The flag is triggered when ALL floating gates reach the trip point Vₜₚ=(V_{dd}−Vₜₕ−I_{flag}*R_{flag}), where V_{dd} is the supply voltage, Vₜₕ is the absolute value of the threshold voltage of the flag PMOS device, I_{flag} is the current through the flag termination current source and R_{flag} is the resistor connected to the supply. By changing I_{flag,} the flag threshold is changed, ensuring that the injection devices will be ON when selected in write mode. I_{flag} is proportional to V_{bg}/R_{bias}, where V_{bg} is the band gap voltage and R_{bias} is the (Nwell) bias resistor in the current reference block. Therefore, the variation in I_{flag} is mainly due to process variations in Nwell resistors, which is removed when the current is forced through R_{flag}, which is also an Nwell resistor. This ensures that the variation in the tunneling flag margin (I_{flag}×R_{flag}) is largely due to the variation Of V_{bg}. The flag is triggered only when the slowest floating gate reaches the trip point. As there can be a significant variation in tunneling rates, this would imply a spread of final gate voltages after erase. For example, a 10× variation in tunneling rates will approximately result in a 200 mV spread in final gate voltages. This spread can be made worse if there is a large variation in the initial states of the gates. However, as tunneling is heavily dependent on Vₒₓ (voltage across the gate oxide), gates with a lower starting point will tunnel at a faster rate, thereby reducing somewhat the effect of different initial states.

The write function operates as follows. During write mode, the desired cell is selected. The corresponding bit-select (Sel0/Sel1) signal is brought to LOW. The gate to be written now has its injection path enabled. Node Vdrn is pulled down to a suitable negative voltage (−2.1 to −3.3) to start the injection process. As electrons are injected onto the floating gate during the injection process, the gate voltage drops and the drain-source current in the injection device increases. However, this is a self-limiting process; injection efficiency reduces as the gate to drain electric field (which depends on V_{gd}, the gate to drain voltage) diminishes. As the gate potential continues to drop, most of the current starts to flow through the device in the read differential pair connected to the gate being injected. Consequently, Ibias_{—}1u (the common “source” node of the differential pair) follows the gate while being positively offset by a threshold voltage plus the overdrive of the device. Once the gate drops sufficiently low, the current through PM9 in the bias block is enough to overcome the two pull-down current sources, NM8 and NM4 (1 uA and 2 uA respectively) (FIG. 23). This changes the output of the detect circuit from LOW to HIGH which turns off NM3 (FIG. 23) and the 2uA current source NM4 (FIG. 23), ensuring that the output is now firmly HIGH. This system of hysteresis ensures that as node Vdrn is increased to ground following the conclusion of injection, the corresponding capacitive increase in the floating gate potential will not change the state of the Done signal. The common source amplifying stage (FIG. 23) consisting of PM24 and NM1 sharpens the edge of the injection done signal, which can take up to 100's of microseconds to transition. The Done signal forces the bit-select signal (Sel0/Sel1) HIGH cutting off the injection path. This ends the write process in the corresponding memory cell. At the top-level, the signal Done_nmos is connected (with corresponding signals from all cells in a memory array) as a wired-AND gate to generate a global Injection_done signal. Detecting the end of injection in this manner ensures that the differential voltage between the two floating gates is much higher than the overdrive of the differential pair.

Capacitors PM2 and PM5 (FIG. 21) increase the overlap capacitance from the floating gate to node Vdrn by a factor of two for the same corresponding increase in width of the injection device. This capacitance ensures that the gate of the selected injection device is at least a threshold below the supply voltage. Consequently, the device turns on immediately and the injection process is jump-started.

The read function operates as follows. To read the content of a cell, a current of about 1 uA is fed to node “Ibias_{—}1u”. Depending on the voltages on “Vfg0” and “Vfg1”, this current will be passed through either transistor PM3 or PM4 and be amplified by a sense amplifier connected to “Amp_fg1” and “Amp_fg0”. For state “1”, Vfg1=−0.2V, and Vfg0=1V, so most of the current will pass through PM3 and be detected by the sense amp as a state “1”. Similarly, for state “0”, Vfg0=−0.2V, and Vfg1=1V, most of the current will pass through PM4 and be detected by sense amp as a state “0”.

While embodiments and applications of this invention have been shown and described, it would be apparent to those skilled in the art having the benefit of this disclosure that many more modifications than mentioned above are possible without departing from the inventive concepts herein. For example, it is to be noted that while the present invention may be implemented in a single well single poly process and will work with low voltage processes (e.g., <=3 volts), the invention is not so limited and can be implemented in processes that support multiple polysilicon layers, multiple wells, and/or in higher voltage devices. Furthermore, the concept of an n-well as used herein is intended to encompass not only conventional n-well devices, but also NLDD (N-type Lightly Doped Drain) devices and other lightly doped, or isolated structures that increase the reliable gate-drain and drain-source voltages of the device so that it, in effect, behaves like a conventional n-well device in this respect. It may also be implemented in thin film above the substrate with equivalent thin film structures. Finally, because the charge on the floating gates can be carefully and precisely written, it is possible to use these structures, coupled with a higher resolution readout circuit, known in the prior art, to store more than one digital bit per cell. With the cells disclosed herein, it would be straightforward to store four different levels of charge, for example using the cell of FIG. 15. Instead of a single reference half-pair FG0 that stores a charge value ½, there could be three reference half-pairs FG0_A, FG0_B, and FG0_C, storing values ¼, ½, and ¾ respectively. During readout the sense amplifier would compare the value stored on one floating gate, say FG1, with FG0_A, FG0_B, and FG0_C in turn. If the value stored on FG1 is less than that on FG0_A, then FG1 stores a zero. If the value on FG1 is greater than FG0_A but less than FG0_B, then FG1 stores a one. If the value on FG1 is greater than FG0_B but less than FG0_C, then FG1 stores a two. If the value on FG1 is greater than FG0_C, then FG1 stores a three. By storing four discernable charge values, each half-cell holds two bits of information. This approach is clearly extensible to storing three or more bits per cell, limited only by the accuracy of the write, retention, and read processes. The invention, therefore, is not to be restricted except in the spirit of the appended claims.

What is claimed is:

1. An electrically eraseable programmable read-only memory (EEPROM), comprising:
a first pFET floating gate transistor coupled to a first floating gate;
a second pFET floating gate transistor coupled to a second floating gate; and
a differential sense amplifier coupled to receive drain currents from said first pFET floating gate transistor and said second pFET floating gate transistor.

2. The EEPROM in accordance with claim 1, further comprising:
a first tunneling junction coupled to remove electrons from said first floating gate; and
a second tunneling junction coupled to remove electrons from said second floating gate.

3. The EEPROM in accordance with claim 1, further comprising:
a window for coupling actinic light to said first and second floating gates to thereby remove electrons from them.

4. An electrically eraseable programmable read-only memory (EEPROM), comprising:
a first means for storing charge;
a second means for storing charge;
a third means for adding charge to said first means;
a fourth means for adding charge to said second means;
a fifth means for removing charge from said first means;
a sixth means for removing charge from said second means; and
a seventh means coupled to said first and second means for sensing which of said first means and said second means is storing a greater amount of charge.

5. The EEPROM in accordance with claim 1, further comprising:
a first select switch coupled in series with said first pFET floating gate transistor; and
a second select switch coupled in series with said second pFET floating gate transistor, said first and second select switches controlled by signals applied thereto to determine which of said first floating gate and said second floating gate may undergo charge injection at a given time.

6. The EEPROM in accordance with claim 2, further comprising:
a first select switch coupled in series with said first pFET floating gate transistor; and
a second select switch coupled in series with said second pFET floating gate transistor, said first and second select switches controlled by signals applied thereto to determine which of said first floating gate and said second floating gate may undergo charge injection at a given time.

7. The EEPROM in accordance with claim 4, further comprising:
an eighth means coupled in series with said first third means for controlling the operation of said third means; and
a ninth means coupled in series with said fourth means for controlling the operation of said fourth means.

8. An electrically eraseable programmable read-only memory (EEPROM), comprising:
a first pFET floating gate transistor coupled to a first floating gate;
a second pFET floating gate transistor coupled to a second floating gate;
a first gate of a first transistor coupled to said first floating gate;
a second gate of a second transistor coupled to said second floating gate; and
a source of a bias current coupled to pass current from a single node in parallel through said first and said second transistor to a differential sense device, charge on said first floating gate and said second floating gate controlling the flow of current through said respective first and second transistors.

9. The EEPROM in accordance with claim 8, wherein said first and second transistors are pFETs.

10. The EEPROM in accordance with claim 9, further comprising a first tunneling junction coupled to remove electrons from said first floating gate and a second tunneling junction coupled to remove electrons from said second floating gate.

11. The EEPROM in accordance with claim 9, wherein said first and second transistors are pFETs.

12. The EEPROM in accordance with claim 11, further comprising a first select switch coupled in series with said first pFET floating gate transistor and a second select switch coupled in series with said second pFET floating gate transistor.

13. The EEPROM in accordance with claim 12, wherein said first select switch and said second select switch are pFET transistors.

14. The EEPROM in accordance with claim 8, further comprising a first enable switch coupled in series with said first transistor and a second enable switch coupled in series with said second transistor, said enable switches controlling the flow of current to said differential sense device.

15. The EEPROM in accordance with claim 1, further comprising:
a first control gate coupled between a first control input node and said first floating gate; and
a second control gate coupled between a second control input node and said second floating gate.

16. The EEPROM in accordance with claim 15, further comprising:
a first tunneling junction coupled to remove electrons from said first floating gate; and
a second tunneling junction coupled to remove electrons from said second floating gate.

17. An electrically eraseable programmable read-only memory (EEPROM), comprising:
a first pFET floating gate transistor coupled to a first floating gate;
a second pFET floating gate transistor coupled to a second floating gate;
a first gate of a first transistor coupled to said first floating gate;
a second gate of a second transistor coupled to said second floating gate;
a source of a bias current coupled to pass current from a single node in parallel through said first and said second transistor to a differential sense device, charge on said first floating gate and said second floating gate controlling the flow of current through said respective first and second transistors;
a first control gate coupled between a first control input node and said first floating gate; and
a second control gate coupled between a second control input node and said second floating gate.

18. The EEPROM in accordance with claim 17, further comprising:
a first tunneling junction coupled to remove electrons from said first floating gate; and
a second tunneling junction coupled to remove electrons from said second floating gate.

19. A method for storing information in a semiconductor device, the semiconductor device having a first floating gate and a second floating gate, each said floating gate coupled to the gate of a corresponding first and second floating gate pFET, said method comprising:
placing a charge onto said first floating gate;
placing a charge onto said second floating gate;
removing charge from said first floating gate;
removing charge from said second floating gate; and
measuring charge on said first floating gate and said second floating gate simultaneously.

20. A method for storing multiple bits of information in a semiconductor device, the semiconductor device having a first floating gate and a second floating gate, each said floating gate coupled to the gate of a corresponding first and second floating gate pFET, said method comprising:
placing a first charge having one of a plurality of levels onto said first floating gate;
placing a second charge having one of a plurality of levels onto said second floating gate;
measuring said first charge on said first floating gate to determine which level of charge is stored thereon;
measuring said second charge on said second floating gate to determine which level of charge is stored thereon; and
determining a multi-bit output based upon said measuring said first charge and said measuring said second charge.

21. A method for storing multiple bits of information in a semiconductor device, the semiconductor device having a first floating gate and a second floating gate, each said floating gate coupled to the gate of a corresponding first and second floating gate pFET, said method comprising:
placing a first charge having one of a plurality of levels onto said first floating gate;
placing a second charge having one of a plurality of levels onto said second floating gate;
comparing the first charge magnitude with the second charge magnitude;
comparing at least one of said first charge magnitude and said second charge magnitude with a known charge magnitude; and
determining a multi-bit value stored in the semiconductor device based upon said comparing the first charge magnitude and said comparing at least one.

22. An electrically eraseable programmable read-only memory (EEPROM), comprising:
a first pFET floating gate transistor coupled to a first floating gate;
a plurality of second pFET floating gate transistors, each coupled to a corresponding separate floating gate and having their drains and sources coupled in common through at least one select switch per transistor; and
a differential sense amplifier coupled to receive drain currents from said first pFET floating gate transistor and a selected one of said second pFET floating gate transistors.

23. An electrically eraseable programmable read-only memory (EEPROM), comprising:
a first pFET floating gate transistor coupled to a first floating gate and having its source coupled through a select switch to a bias node;
a plurality of second pFET floating gate transistors, each coupled to a corresponding separate floating gate and having their sources through at least one select switch per transistor to said bias node and also having their drains coupled together and to a drain node; and
a differential sense amplifier coupled to said drain node and to a drain of said first pFET floating gate transistor, a select signal selecting one of said plurality of second pFET floating gate transistors.
